(19) United States
(12) Patent Application Publication
(10) Pub. No.: US 2026/0358405 A1
(43) Pub. Date: Nov. 12, 2026

(54) APPARATUS AND METHOD OF TESTING DEVICES-UNDER-TEST

(71) Applicant: Taiwan Semiconductor Manufacturing Company, Ltd., Hsinchu (TW)

(72) Inventors: Chu-Feng LIAO, Hsinchu (TW); Shuo-Wen CHANG, Hsinchu (TW); Yuan-Yao CHANG, Hsinchu (TW)

(73) Assignee: Taiwan Semiconductor Manufacturing Company, Ltd., Hsinchu (TW)

(21) Appl. No.: 19/203,008

(22) Filed: May 8, 2025

(51) Int. Cl. G01R 31/28

(52) U.S. Cl. CPC G01R 31/2856; G01R 31/2831; G01R 31/2868; G01R 31/2879

(57) ABSTRACT

An embodiment testing apparatus for testing a plurality of devices-under-test (DUTs) includes a first interface terminal configured as a measurement node, a second interface terminal configured as a stress node, and a switch device including a first common node and a plurality of branch nodes electrically connectable to the plurality of DUTs. The switch device is configured to electrically couple the first common node to one of the plurality of branch nodes at a time. The testing apparatus further includes one or more conductive path networks corresponding to one or more conductive nodes that are electrically connectable to corresponding one or more groups of DUTs of the plurality of DUTs, and a path selection device configured to electrically couple the measurement node to the first common node, or to electrically couple the stress node to one of the one or more conductive nodes.

### BACKGROUND

The semiconductor integrated circuit (IC) industry has experienced rapid growth. Technological advances in IC materials and design have produced generations of ICs where each generation has smaller and more complex circuits than the previous generation. In some applications, to ensure the quality, reliability, and/or yield of the manufactured semiconductor devices, one or more testing processes are performed at various levels, including a wafer-level test that measures, tests, and/or monitors certain parameters of a set of process control monitoring (PCM) components or structures (also referred to as devices-under-test, or DUTs) on a semiconductor wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic diagram of a testing configuration based on a processing device for performing a wafer-level test on a wafer, in accordance with some embodiments.

FIG. 1B is a plan view of a wafer, in accordance with some embodiments.

FIG. 1C is a schematic diagram of a test line on the wafer, in accordance with some embodiments.

FIG. 2A is a schematic diagram of a test line example configured to apply a stress condition to a group of devices-under-test (DUTs) at a time, in accordance with some embodiments.

FIG. 2B is a schematic diagram of the test line example in FIG. 2A configured to measure one or more parameters of the group of DUTs at a time, in accordance with some embodiments.

FIG. 2C is a schematic diagram of a switch device and a switch control, in accordance with some embodiments.

FIG. 3 is a schematic diagram of a portion of another test line example, in accordance with some embodiments.

FIG. 4 is a schematic diagram of a portion of a path selection device, in accordance with some embodiments.

FIGS. 5A-5C are schematic diagrams of switch device examples in conjunction with other components in a test line, in accordance with some embodiments.

FIGS. 6A-6C are various views of metallization layers as the basis for forming and testing DUTs, in accordance with some embodiments.

FIGS. 7A-7B are various views of a transistor example as the basis for forming and testing DUTs, in accordance with some embodiments.

FIG. 8 is a flowchart of a method of testing a plurality of DUTs on a wafer, in accordance with some embodiments.

FIG. 9 is a block diagram of an IC manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components and arrangements are described below to simplify this disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, this disclosure may repeat reference numerals and/or letters in the various examples. This repetition is for simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, the term “made of” may mean either “including” or “consisting of.” In this disclosure, the phrase “one of A, B, and C” means “A, B, and/or C” (A, B, C, A and B, A and C, B and C, or A, B and C), and does not mean one element from A, one element from B, and one element from C, unless otherwise described.

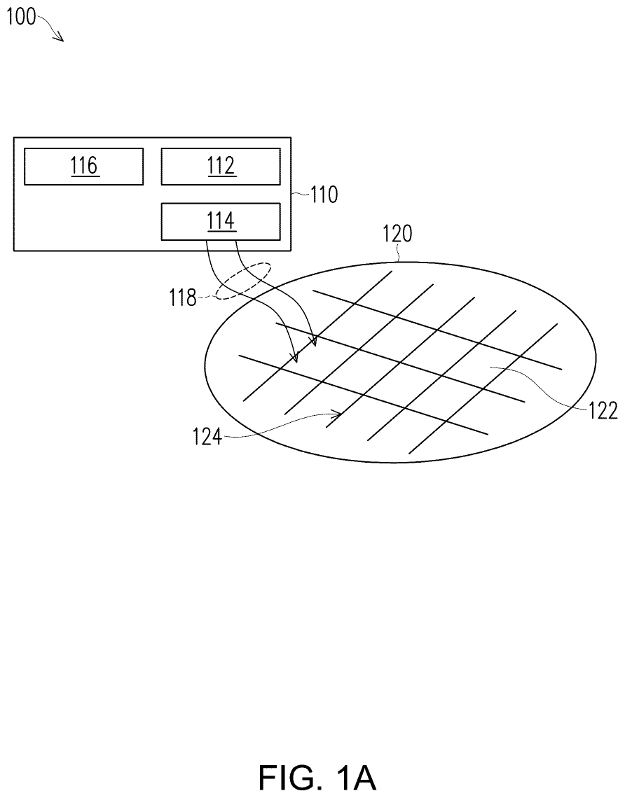

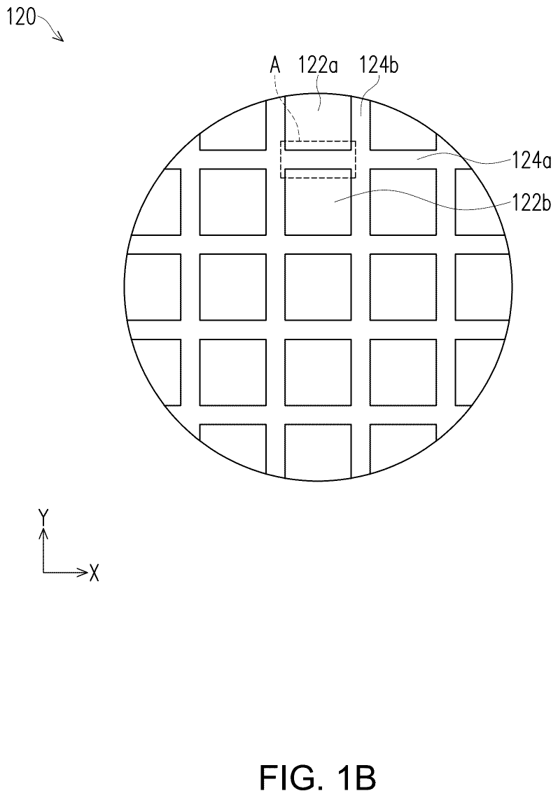

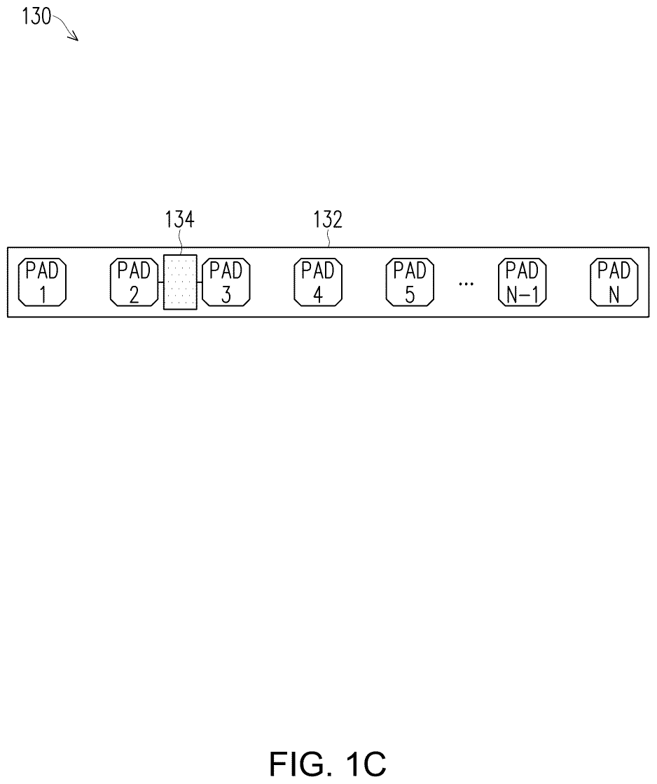

FIG. 1A is a schematic diagram of a testing configuration 100 based on a processing device 110 for performing a wafer-level test on a wafer 120, in accordance with some embodiments. In FIG. 1A, wafer 120 includes die areas 122 corresponding to formed integrated circuit (IC) dies on wafer 120. In FIG. 1A, testing configuration 100 is for testing one or more devices-under test (DUTs) on wafer 120 in order to obtain one or more parameters of the one or more DUTs. In some embodiments, whether wafer 120 and/or IC dies meet all the manufacturing requirements is determinable based on the one or more parameters of the one or more DUTs. In some embodiments, testing configuration 100 is usable for testing wafer 120 by a manufacturer before the wafer is shipped to a client or for subsequent processing. In some embodiments, testing configuration 100 is usable for testing wafer 120 by the client for verifying the wafer 120 during a wafer acceptance test (WAT).

In this non-limiting example, wafer 120 further includes scribe lines 124 defined between adjacent die areas 122 such that the IC dies formed in die areas 122 are separable along scribe lines 124. In some embodiments, one or more interface terminals (e.g., conductive pads) are within scribe lines 124 and are electrically coupled to the one or more DUTs. In this non-limiting example, processing device 110 is configured to configure, control, and/or measure the one or more DUTs through the one or more interface terminals within scribe lines 124. In some embodiments, the one or more DUTs are in one or more of scribe lines 124, within one or more of die areas 122, or both.

In some embodiments, processing device 110 includes hardware and software components that provide a suitable operational and functional environment for the tests. In some embodiments, processing device 110 includes a test generator 112, a coupler 114, and a test analyzer 116. In some embodiments, test generator 112 is configured to generate one or more signals for setting up a test and/or providing input signals for the test. In some embodiments, coupler 114 is configured to provide the one or more signals from test generator 112 to the one or more DUTs on wafer 120. In some embodiments, coupler 114 is configured to provide the one or more signals to the one or more DUTs based on a set of probes 118.

In some embodiments, for performing a test, the set of probes 118 are moved toward and electrically coupled to the one or more interface terminals (e.g., conductive pads) within scribe lines 124 on wafer 120. In some embodiments, the one or more interface terminals include an interface terminal for carrying a positive supply voltage (e.g., VDD), an interface terminal for carrying a negative supply voltage (e.g., VSS), an interface terminal for carrying a ground reference voltage (e.g., GND), an interface terminal for carrying an input (digital or analog) signal, an interface terminal for carrying an output (digital or analog) signal, or the like, or a combination thereof. In some embodiments, processing device 110 is configured to provide suitable supply voltage(s) and input signal(s) to a subset of the one or more interface terminals and corresponding probes of the set of probes 118, and receive output signal(s) from another subset of the one or more interface terminals and corresponding probes of the set of probes 118.

Moreover, test analyzer 116 receives the output signal(s) from the one or more DUTs through the set of probes 118 and coupler 114, and is configured to extract the one or more parameters of the one or more DUTs and/or determine whether the one or more DUTs meet the corresponding requirements based on the output signal(s) and/or the extracted one or more parameters.

FIG. 1B is a plan view of wafer 120 in FIG. 1A, in accordance with some embodiments. Components in FIG. 1B that are the same or similar to those in FIG. 1A are given the same reference numbers, and the description thereof is simplified or omitted.

In FIG. 1B, wafer 120 includes a plurality of die areas (such as die areas 122a and 122b) arranged in rows and columns for forming corresponding IC dies. In FIG. 1B, adjacent rows of die areas define the scribe lines (e.g., scribe line 124a) extending along a row direction (e.g., the X direction), and adjacent columns of die areas define the scribe lines (e.g., scribe line 124b) extending along a column direction (e.g., the Y direction). In some embodiments, each one of the IC dies on wafer 120 includes corresponding circuitry. In some embodiments after completion of wafer 120, the IC dies formed in the die areas (such as die areas 122a and 122b) are separated along the scribe lines in a subsequent die singulation process based on, e.g., sawing along the scribe lines. In some embodiments, the circuity of the IC dies is based on interconnecting various components, such as transistors, diodes, resistors, capacitors, inductors, or the like, or a combination thereof.

In some embodiments, testing individual components is not possible or feasible once the components are integrated into the corresponding circuitry. In order to verify that the components on wafer 120 are fabricated according to the design specification, the one or more DUTs are manufactured and tested instead. In some embodiments, the one or more DUTs include components that are configured to mimic the properties or characteristics of their counterparts (and/or within a range of variations for verification or modeling) since they are fabricated using the same set of manufacturing processes. As such, the measured properties or characteristics of the DUTs provide a good indication of the properties or characteristics of various components in the circuitry of the IC dies.

In some embodiments, the one or more interface terminals (e.g., conductive pads) for accessing the one or more DUTs are within the scribe lines to minimize the additional areas occupied by these interface terminals. In some embodiments, a portion or all of the one or more DUTs are within the scribe lines. In some embodiments, a portion or all of the one or more DUTs are within the IC die areas without hindering the circuitry of the IC corresponding dies. In some embodiments, a set of interface terminals within a segment of a scribe line (e.g., in area A in FIG. 1B), the DUTs to be tested using the set of interface terminals, and the associated selection or interconnection structures are also collectively referred to as a test line.

FIG. 1C is a schematic diagram of a test line 130 on semiconductor wafer 120 in FIGS. 1A and 1B, in accordance with some embodiments. In this example, test line 130 includes a plurality of interface terminals (e.g., conductive pads) within a segment 132 of a scribe line that is in area A in FIG. 1B. In some embodiments, one or more other test lines similar to test line 130 are formed based on other portions of scribe lines of wafer 120. In some embodiments, test line 130 is usable to test, verify, or monitor the quality of the manufacturing process and/or to exam or observe the variations of various components formed on wafer 120.

In FIG. 1C, test line 130 includes N interface terminals (e.g., conductive pads) labeled as “PAD 1,” “PAD 2,” “PAD 3,” “PAD 4,” “PAD 5,” “PAD N−1,” and “PAD N,” where N is a positive integer greater than one (1). In some embodiments, test line 130 further includes one or more DUTs electrically coupled to one or more of the interface terminals of test line 130 through one or more interconnection structures (e.g., conductive paths based on metallization layers). In FIG. 1C, as a non-limiting example, a DUT 134 is formed within segment 132 of a scribe line and electrically coupled between interface terminals PAD 2 and PAD 3. In some embodiments, the number of the interface terminals is set based on the floor plan and/or the available area of wafer 120. In some embodiments, each test line includes 22 interface terminals. In some embodiments, the interface terminals are configured to carry a positive supply voltage (e.g., VDD), a negative supply voltage (e.g., VSS), a ground reference voltage (e.g., GND), an input (digital or analog) signal, an output (digital or analog) signal, or the like, or a combination thereof. In some embodiments, the test generator 112 and/or test analyzer 116 in FIG. 1A are configured to configure the supply voltages, provide input signals, and receive output signals through coupler 114 and probes 118 electrically coupled to the interface terminals of test line 130.

In some applications, multiple DUTs are electrically coupled to the interface terminals, and one or more stress conditions (e.g., high temperature conditions or high voltage conditions) are applied to the DUTs one DUT at a time through corresponding ones of the plurality of interface terminals of the test lines. In contrast, according to one or more embodiments of the present disclosure, the DUTs included in a test line are arranged into one or more groups of DUTs, where the DUTs of each group of the one or more groups of DUTs are subject to the application of a same stress condition. According to one or more embodiments of the present disclosure, the stress conditions are applied to the DUTs one group at a time. As such, according to one or more embodiments of the present disclosure, the time for applying stress conditions to the DUTs is reduced, and the efficiency of testing the DUTs is therefore improved. Also, by sharing the same interface terminal(s) for the application of different stress conditions, the interface terminals in the scribe lines are more efficiently used, or more DUTs may be tested without additional interface terminals.

In some embodiments, a test line and the DUTs included therein are arranged to enable efficient observation of reliability of metallization structures and semiconductor devices under various stress conditions (e.g., high voltage and/or high temperature stress conditions). According to one or more embodiments of the present disclosure, the weakness of the DUTs (as well as the components on the wafer the DUTs represent), together with the corresponding aging model are determined efficiently. In some embodiments, a test line is suitable to be embedded in a semiconductor device suitable for a three-dimensional IC (3DIC) application for testing and/or monitoring various components (e.g., for testing and/or monitoring back side power rails of a die) in the 3DIC application.

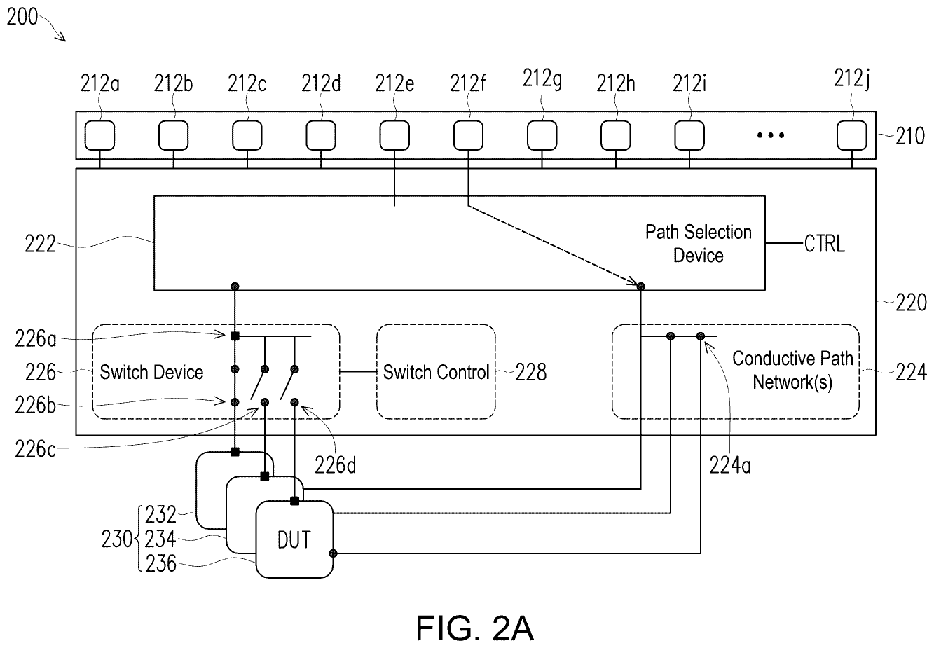

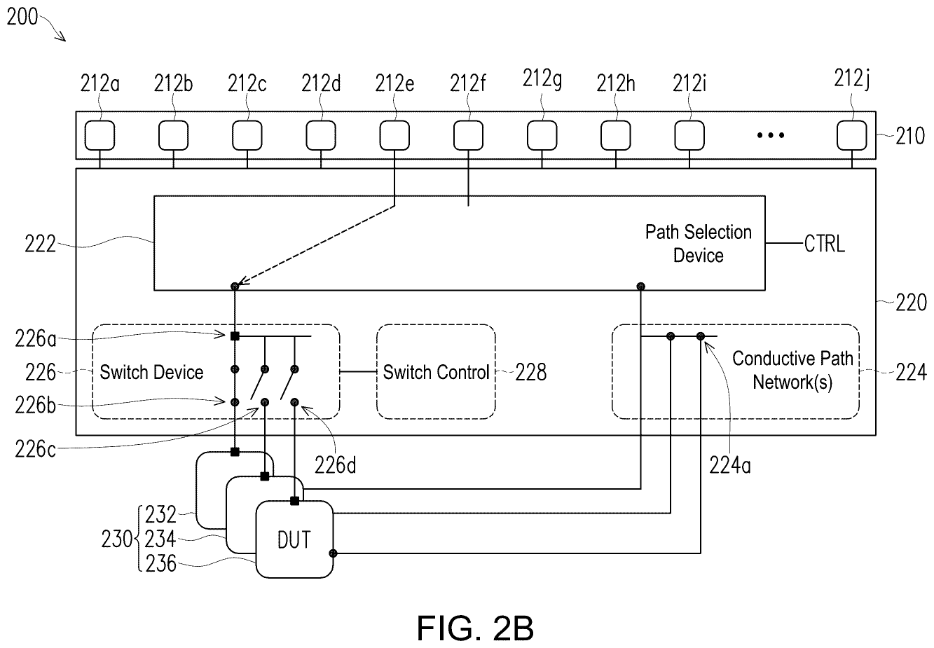

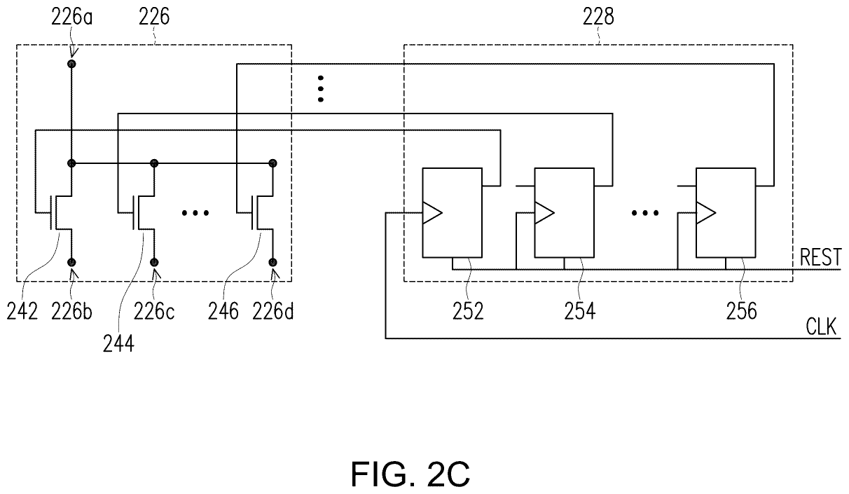

FIG. 2A is a schematic diagram of a test line example 200 configured to apply a stress condition to a group of DUTs at a time, in accordance with some embodiments. In some embodiments, the schematic diagram in FIG. 2A is a simplified schematic diagram of test line example 200, and various components or details are simplified or omitted.

In some embodiments, test line example 200 is on a wafer that includes one or more die areas (e.g., die areas 122a and 122b in FIG. 1B) corresponding to formation of one or more dies and a scribe line 210 (e.g., scribe lines 124a and 124b in FIG. 1B) adjacent to the one or more die areas. In FIG. 2A, test line example 200 includes one or more interface terminals (e.g., interface terminals 212a-212j, corresponding to conductive pads) in scribe line 210. In this example, test line example 200 further includes a set of selection or interconnection structures 220 and a plurality of DUTs 230 (e.g., including DUTs 232, 234, and 236). In some embodiments, a portion or all of the set of selection or interconnection structures 220 is in scribe line 210 and/or the one or more die areas. In some embodiments, a portion or all of the plurality of DUTs 230 is in scribe line 210 and/or the one or more die areas.

In FIG. 2A, the one or more interface terminals include a first interface terminal 212e configured as a measurement node and a second interface terminal 212f configured as a stress node. In some other embodiments, first interface terminal 212e is configured as the measurement node and the stress node. In this non-limiting example, the set of selection or interconnection structures 220 includes a path selection device 222, a switch device 226, and a switch control 228. Switch device 226 includes a common node 226a and a plurality of branch nodes 226b, 226c, and 226d. In some embodiments, each one of the plurality of branch nodes 226b, 226c, and 226d is electrically connectable to a corresponding DUT (e.g., DUTs 232, 234, and 236) of the plurality of DUTs 230. In some embodiments, based on control signals from switch control 228, switch device 226 is configured to electrically couple common node 226a to one of the plurality of branch nodes 226b, 226c, and 226d at a time.

In this non-limiting example, the plurality of DUTs 230, including DUTs 232, 234, and 236, is configured as a group of DUTs subjected to the application of a same stress condition. In some embodiments, one or more conductive path networks 224 includes a conductive path network 224a corresponding to a conductive node that is electrically connectable to the DUTs 232, 234, and 236 as a group of DUTs of the plurality of DUTs 230. Moreover, in some embodiments, based on a set of control signals CTRL, path selection device 222 is configured to electrically couple the measurement node (e.g., corresponding to first interface terminal 212e) to common node 226a, or to electrically couple the stress node (e.g., corresponding to second interface terminal 212f) to the conductive node (e.g., corresponding to conductive path network 224a). In some embodiments, path selection device 222 includes one or more switches, one or more multiplexers, one or more demultiplexers, or the like, or a combination thereof.

In FIG. 2A as a non-limiting example, path selection device 222 is set to electrically couple second interface terminal 212f (i.e., the stress node) to the conductive node (e.g., corresponding to conductive path network 224a) of one or more conductive path networks 224. In some embodiments, in FIG. 2A as a non-limiting example, path selection device 222 is also set to electrically decouple first interface terminal 212e (i.e., the measurement node) from common node 226a of switch device 226. Based on the configuration in FIG. 2A, test line example 200 is usable to apply one or more stress conditions to the plurality of DUTs 230 at the same time. In some embodiments, the one or more stress conditions include applying a high voltage (e.g., 1.5 times, 2.0 times, 3.0 times, or more of a nominal voltage level of a node), a reversed voltage (e.g., applying a negative voltage to a node configured to receive a positive voltage), or a high current (e.g., 1.5 times, 2.0 times, 3.0 times, or more of a nominal current capacity of a node) to the plurality of DUTs 230.

FIG. 2B is a schematic diagram of test line example 200 in FIG. 2A configured to measure one or more parameters of the group of DUTs at a time, in accordance with some embodiments. Components in FIG. 2B that are the same or similar to those in FIG. 2A are given the same reference number or reference labels, and the description thereof is simplified or omitted.

In FIG. 2B as a non-limiting example, path selection device 222 is set to electrically couple first interface terminal 212e (i.e., the measurement node) to common node 226a of switch device 226. In some embodiments, in FIG. 2B as a non-limiting example, path selection device 222 is also set to electrically decouple second interface terminal 212e (i.e., the stress node) from the conductive node (e.g., corresponding to conductive path network 224a) of one or more conductive path networks 224. Based on first interface terminal 212e (i.e., the measurement node) being electrically coupled to common node 226a of switch device 226, switch device 226 electrically couples common node 226a to one of the plurality of branch nodes 226b, 226c, and 226d at a time, such that a processing device (e.g., processing device 110 in FIG. 1A) measures signals from first interface terminal 212e (i.e., the measurement node) indicating the measurement results of individual DUTs 232, 234, and 236 of the plurality of DUTs 230.

In some embodiments, the set of control signals CTRL is obtained from one or more interface terminals (e.g., a portion or all of interface terminals 212a-212d and interface terminals 212g-212j). In some embodiments, the set of selection or interconnection structures 220 further includes a selection control circuitry configured to decode or convert the set of control signals CTRL into a set of selection signals. In some embodiments, a bit width of the set of control signals CTRL is less than a bit width of the set of selection signals. In some embodiments, the set of selection or interconnection structures 220 does not include the selection control circuitry, and is controllable based on the set of control signals CTRL as the set of selection signals without further decoding or conversion.

In the example in FIGS. 2A and 2B, two different interface nodes (e.g., first interface terminal 212e and second interface terminal 212f) are configured as a measurement node and a stress node. In some other embodiments, one interface node is configured as the measurement node and the stress node, based on how the interface node is electrically coupled to a conductive path network (e.g., one of one or more conductive path networks 224) for applying a stress condition to a group of DUTs or to a switch device (e.g., switch device 226) for measuring the DUTs. Also, in some other embodiments, other interface nodes (e.g., interface terminals 212a-212d and interface terminals 212g-212j) in scribe line 210 are usable to apply stress conditions and measure other groups of DUTs in a manner similar to the example in FIGS. 2A-2B, or in a manner similar to the examples in FIGS. 2A-2B.

In the example in FIGS. 2A and 2B, the plurality of DUTs 230 to be measured through a measurement node (e.g., interface terminal 212e) includes one group of DUTs for the purpose of applying the corresponding stress conditions through a stress node (e.g., interface terminal 212f). In some embodiments, the plurality of DUTs to be measured through a measurement node includes one or more groups of DUTs for the purpose of applying the corresponding stress conditions through a stress node. In some embodiments, one group of DUTs includes at least two DUTs and up to hundreds or even thousands of DUTs.

FIG. 2C is a schematic diagram of switch device 226 and switch control 228 in FIGS. 2A-2B, in accordance with some embodiments. Components in FIG. 2C that are the same or similar to those in FIGS. 2A and 2B are given the same reference numbers, and the description thereof is simplified or omitted. In some embodiments, the schematic diagram in FIG. 2C is a simplified schematic diagram of switch device 226 and switch control 228 as a non-limiting example, and various components or details are simplified or omitted.

In FIG. 2C, switch device 226 includes a plurality of transistors 242, 244, and 246 electrically coupled between common node 226a and the plurality of branch nodes 226b, 226c, and 226d. Also, switch control 228 includes a plurality of flip-flop circuits 252, 254, and 256 arranged in series. In FIG. 2C, the data output node of each one of the flip-flop circuits 252, 254, and 256 is electrically coupled to a gate terminal of a corresponding one of the plurality of transistors 242, 244, and 246. In FIG. 2C, the data output node of a previous flip-flop circuit of the plurality of flip-flop circuits (e.g., flip-flop circuits 252 and 254) is electrically coupled to a data input node of a next flip-flop circuit of the plurality of flip-flop circuits (e.g., flip-flop circuits 254 and 256), except the data input node of the first flip-flop circuit 252 is set to a predetermined logic value. The clock nodes of the plurality of flip-flop circuits 252, 254, and 256 are configured to receive a clock signal CLK, and the reset nodes of the plurality of the plurality of flip-flop circuits 252, 254, and 256 are configured to receive a reset signal REST.

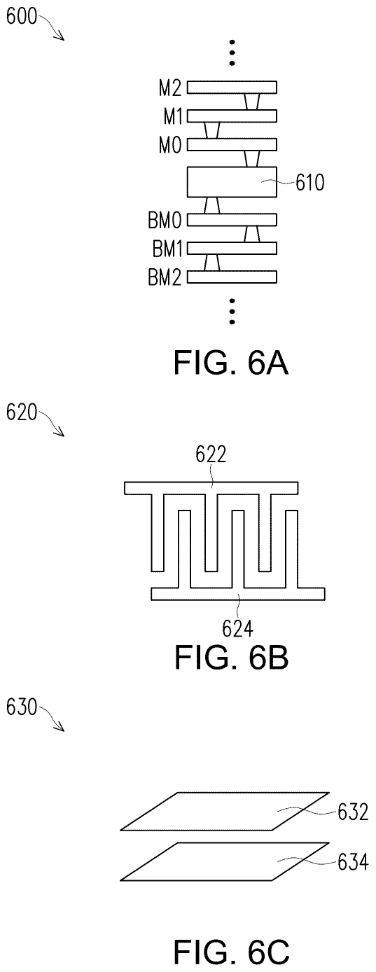

In this non-limiting example, each one of the plurality of flip-flop circuits 252, 254, and 256 is configured to control an on or off state of a corresponding one of the plurality of transistors 242, 244, and 246. In this example, the plurality of transistors 242, 244, and 246 is configured to be turned on, one at a time, based on toggling the clock signal CLK. In some other embodiments, each one of the plurality of flip-flop circuits 252, 254, and 256 is configured to control an on or off state of two or more transistors of different set of transistors in conjunction with the examples in FIGS. 6B-6C.

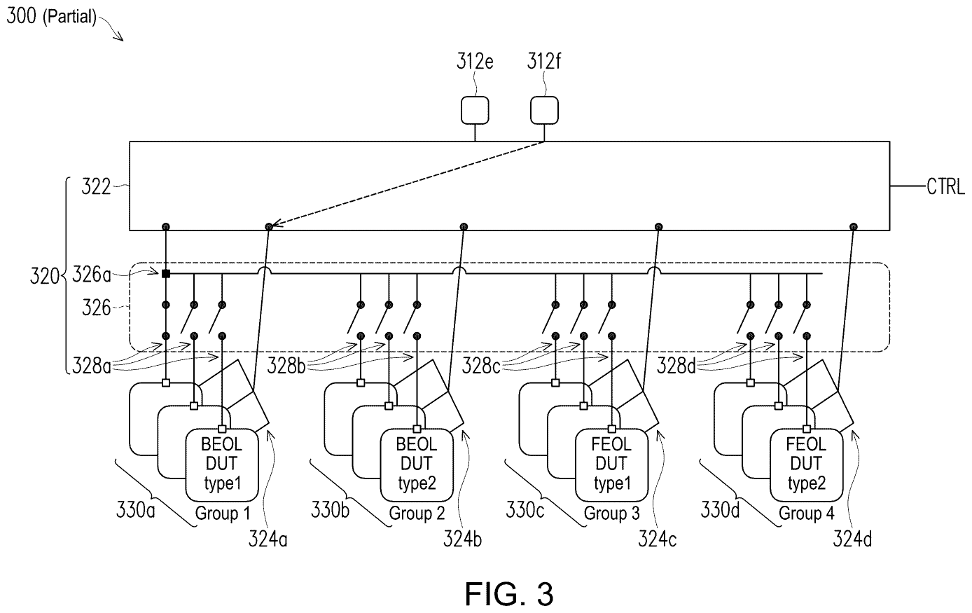

FIG. 3 is a schematic diagram of a portion of another test line example 300 (labeled as “300 (Partial)”), in accordance with some embodiments. In some embodiments, test line example 300 is a variation or a generalization of test line example 200. In some embodiments, the schematic diagram in FIG. 3 is a simplified schematic diagram of test line example 300, and various components or details are simplified or omitted.

In FIG. 3, test line example 300 includes one or more interface terminals (e.g., conductive pads), such as a first interface terminal 312e configured as a measurement node and a second interface terminal 312f configured as a stress node. In some embodiments, first interface terminal 312e and second interface terminal 312f correspond to interface terminals 212e and 212f in FIGS. 2A and 2B. While the schematic diagram in FIG. 3 includes only two interface terminals 312e and 312f in a scribe line, in some embodiments, the scribe line includes one or more other interface terminals not included in the schematic diagram.

In this example, test line example 300 further includes a set of selection or interconnection structures 320 and a plurality of DUTs arranged into one or more groups of DUTs 330a (also labeled as “Group 1”), 330b (also labeled as “Group 2”), 330c (also labeled as “Group 3”), and 330d (also labeled as “Group 4”). In this non-limiting example, the set of selection or interconnection structures 320 of test line example 300 includes a switch device 326 that includes a common node 326a and a plurality of branch nodes 328a, 328b, 328c, and 328d (each reference number corresponding to three branch nodes). In some embodiments, each one of the plurality of branch nodes 328a, 328b, 328c, and 328d is electrically connectable to a corresponding DUT of the plurality of DUTs. In FIG. 3, switch device 326 is configured to electrically couple the common node 326a to one of the plurality of branch nodes 328a, 328b, 328c, and 328d at a time. In some embodiments, one group of DUTs includes at least two DUTs and up to hundreds or even thousands of DUTs.

In some embodiments, each group of the groups of DUTs 330a, 330b, 330c, and 330d is subjected to the application of a same stress condition, and thus is configured to be “stressed” during a same stress process. For example, in FIG. 3, the group of DUTs 330a corresponds to DUTs including back-end-of-line (BEOL) components (e.g., conductive structure based on front side metallization layers, conductive structure based on back side metallization layers, embedded capacitors or resistors based on metallization layers) subject to a first stress condition and labeled as “BEOL DUT type 1”; and the group of DUTs 330a corresponds to DUTs including BEOL components subject to a second stress condition and labeled as “BEOL DUT type 2.” Also, in FIG. 3, the group of DUTs 330c corresponds to DUTs including front-end-of-line (FEOL) components (e.g., semiconductor components on or partially in a substrate, such as transistors or diodes) subject to a third stress condition and labeled as “FEOL DUT type 1”; and the group of DUTs 330d corresponds to DUTs including FEOL components subject to a fourth stress condition and labeled as “FEOL DUT type 2.”

In FIG. 3, the set of selection or interconnection structures 320 of test line example 300 includes one or more conductive path networks 324a, 324b, 324c, and 324d corresponding to one or more conductive nodes that are electrically connectable to corresponding one or more groups of DUTs 330a, 330b, 330c, and 330d. Also, the set of selection or interconnection structures 320 of test line example 300 further includes a path selection device 322 configured to electrically couple the measurement node (e.g., corresponding to interface terminal 312e) to the common node 326a, or to electrically couple the stress node (e.g., corresponding to interface terminal 312f) to one of the one or more conductive nodes (e.g., corresponding to one or more conductive path networks 324a, 324b, 324c, and 324d).

In operation, path selection device 322 is set to electrically couple the stress node (e.g., corresponding to interface terminal 312f) to one of the one or more conductive nodes of a corresponding one of one or more conductive path networks 324a, 324b, 324c, and 324d. For each one of the groups of DUTs 330a, 330b, 330c, and 330d, a stress signal based on a corresponding stress condition is applied from the stress node to the group of DUTs through the corresponding one of the one or more conductive path networks 324a, 324b, 324c, and 324d. In some embodiments, after the stress conditions have been applied to all the groups of DUTs 330a, 330b, 330c, and 330d, path selection device 322 is set to electrically couple the measurement node (e.g., corresponding to interface terminal 312e) to common node 326a of switch device 326. Afterwards, one or more parameters of the DUTs are measurable one DUT at a time.

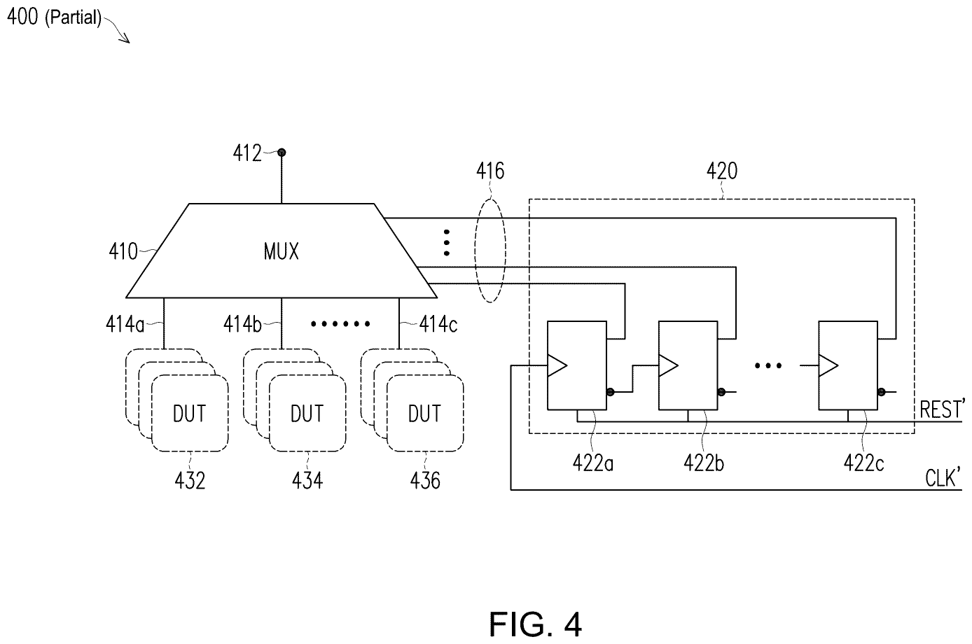

FIG. 4 is a schematic diagram of a portion of a path selection device 400 (labeled as “400 Partial”), in accordance with some embodiments. In some embodiments, path selection device 400 is usable as path selection device 322 in FIG. 3. In some embodiments, the schematic diagram in FIG. 4 is a simplified schematic diagram of path selection device 400, and various components or details are simplified or omitted.

In FIG. 4, path selection device 400 includes a multiplexer 410 (also labeled as “MUX”) that includes a stress node 412 electrically coupled to an interface terminal (e.g., interface terminal 312f in FIG. 3), and a plurality of conductive nodes 414a, 414b, and 414c electrically coupled to corresponding conductive path networks (e.g., conductive path networks 324a, 324b, 324c, and 324d in FIG. 3). The conductive path networks coupled to conductive nodes 414a, 414b, and 414c are electrically connectable to various groups of DUTs 432, 434, and 436. Also, multiplexer 410 is configured to receive a set of selection signals 416 that indicates one of the plurality of conductive nodes 414a, 414b, and 414c to which stress node 412 is electrically coupled.

In FIG. 4, path selection device 400 further includes a selection control circuitry 420 that is configured to receive a set of control signals (e.g., the set of control signals CTRL in FIGS. 2A-3) and convert the set of control signals into the set of selection signals 416. In this example, selection control circuitry 420 includes a counter based on a series of flip-flop circuits 422a, 422b, and 422c, and the set of control signals includes a clock signal CLK' and a reset signal REST'. In FIG. 4 as a non-limiting example, the clock node of the first flip-flop circuit 422a of the series of flip-flop circuits is configured to receive the clock signal CLK'. Also, the data output node of each one of the series of flip-flop circuits is configured to output one of the set of selection signals 416, and the inversed data output node of each one of the series of flip-flop circuits is electrically coupled to a clock node of a next flip-flop circuit of the series of flip-flop circuits. In some embodiments, the inversed data output node of each one of the series of flip-flop circuits is also electrically coupled to the data input node of the same flip-flop circuit (not shown in FIG. 4). In FIG. 4, the reset nodes of the series of flip-flop circuits are configured to receive the reset signal REST'. According to this non-limiting example, the stress node 412 is electrically coupled to each one of the groups of DUTs 432, 434, and 436 one at a time based on the set of selection signals 416 from the series of flip-flop circuits.

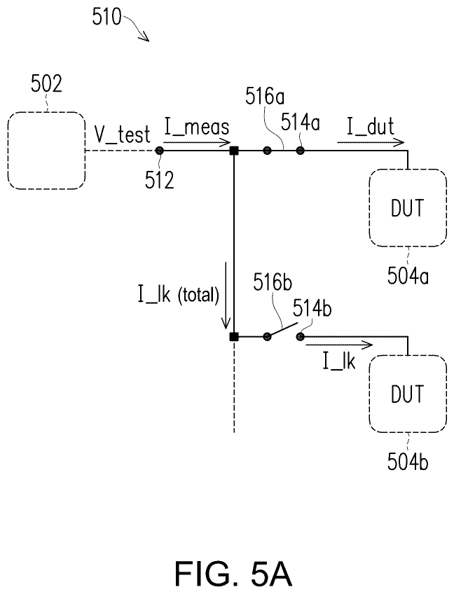

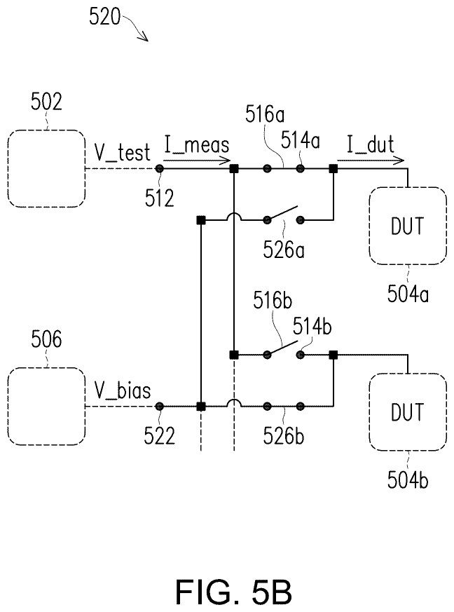

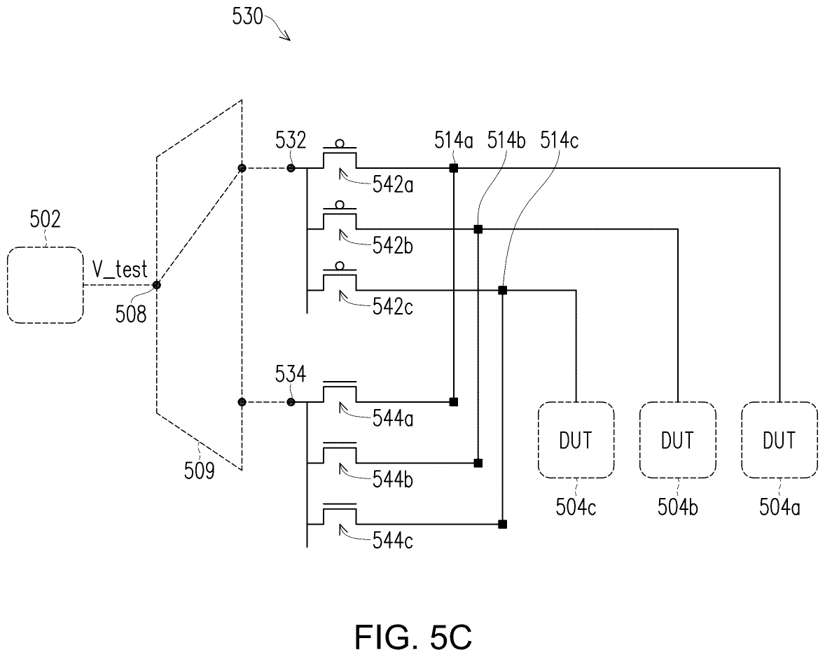

FIG. 5A is a schematic diagram of a first switch device 510 in conjunction with other components in a test line as a non-limiting example, in accordance with some embodiments. In some embodiments, first switch device 510 corresponds to switch device 226 in FIGS. 2A-2B or switch device 326 in FIG. 3.

In FIG. 5A, first switch device 510 includes a common node 512, a plurality of branch nodes 514a and 514b, and a plurality of switches 516a and 516b electrically coupled between common node 512 and the corresponding one of the plurality of branch nodes 514a and 514b. In some embodiments, each one of the plurality of switches 516a and 516b corresponds to a transistor having a first drain/source terminal electrically coupled to common node 512 and a second drain/source terminal electrically coupled to the corresponding one of the plurality of branch nodes 514a and 514b. In some embodiments, the on or off state of each one of the plurality of switches 516a and 516b is controllable based on a switch control, such as switch control 228 in FIGS. 2A-2B or switch control 228 in FIG. 2C with a plurality of flip-flop circuits 252, 254, and 256. While only two switches 516a and 516b are included in FIG. 5A, in some embodiments, a number of switches is based on a number of DUTs in a corresponding group of DUTs.

In FIG. 5A, common node 512 is electrically coupled to an interface terminal 502 that is configured as the measurement node. In some embodiments, interface terminal 502 corresponds to interface terminal 212e in FIG. 2B or interface terminal 312e in FIG. 3. In FIG. 5A, each one of the plurality of branch nodes 514a and 514b is electrically coupled to a corresponding DUT 504a or 504b. In some embodiments, DUTs 504a and 504b correspond to DUTs 230 in FIG. 2B or DUTs 330a, 330b, 330c, and 330d in FIG. 3.

In FIG. 5A, based on switch 516a being set to an on state and other switch(es) of first switch device 510 (e.g., switch 516b) being set to an off state, the measurement node (e.g., corresponding to interface terminal 502) is electrically coupled to DUT 504a. A test voltage (V_test) is observable at common node 512 and causing DUT 504a to draw a DUT current I_dut, which is a parameter to be measured. Ideally, a measured current I_meas of a measurement session should be as close to DUT current I_dut as possible.

However, take branch node 514b coupled to DUT 504b as an example, even if the switch 516b is turned off, a leakage current I_lk in some embodiments is caused by a possible voltage difference between common node 512 and branch node 514b. In some embodiments, the source of leakage current I_lk is based on a subthreshold leakage current and/or a junction leakage current of a transistor that constitutes switch 516b. In some embodiments, first switch device 510 includes N branch nodes and corresponding switches, with one switch on and N-1 switches off during a measurement session. As such, in some embodiments, the N-1 switches cause a total leakage current I_lk(total). In FIG. 5A, the measured current I_meas includes both DUT current I_dut and total leakage current I_lk(total). In some embodiments, the total leakage current I_lk(total) interferes with measuring DUT current I_dut and thus affecting the accuracy of the derived parameters or aging models.

FIG. 5B is a schematic diagram of a second switch device 520 in conjunction with other components in a test line as a non-limiting example, in accordance with some embodiments. In some embodiments, second switch device 520 corresponds to switch device 226 in FIGS. 2A-2B or switch device 326 in FIG. 3. In some embodiments, second switch device 520 is a variation based on first switch device 510. As such, components in FIG. 5B that are the same or similar to those in FIG. 5A are given the same reference numbers, and the description thereof is simplified or omitted.

Compared to first switch device 510, second switch device 520 further includes a second common node 522 and a second plurality of switches 526a and 526b electrically coupled between second common node 522 and the corresponding one of the plurality of branch nodes 514a and 514b. In some embodiments, each one of the second plurality of switches 526a and 526b corresponds to a transistor having a first drain/source terminal electrically coupled to second common node 522 and a second drain/source terminal electrically coupled to the corresponding one of the plurality of branch nodes 514a and 514b. In some embodiments, the on or off state of each one of the plurality of switches 526a and 526b is controllable based on a switch control, such as switch control 228 in FIGS. 2A-2B or switch control 228 in FIG. 2C with a plurality of flip-flop circuits 252, 254, and 256.

In FIG. 5B, second common node 522 is electrically coupled to another interface terminal 506 that is configured as a bias node. In some embodiments, the bias node is configured to carry a direct current (DC) bias voltage V_bias based on a DC voltage component of test voltage V_test at interface terminal 502 and/or common node 512. In some embodiments, interface terminal 506 corresponds to an interface terminal in FIG. 2B other than interface terminals 212e and 212f or an interface terminal in FIG. 3 other than interface terminals 312e and 312f. In some embodiments, switch device 520 is further configured to electrically decouple second common node 522 from one of the plurality of branch nodes 514a and 514b at a time. In some embodiments, each DUT of the plurality of DUTs 504a and 504b is either electrically coupled to common node 512 or to second common node 522 at a time.

In FIG. 5B, based on switch 516a is set to an on state and other switch(s) of second switch device 520 associated with common node 512 (e.g., switch 516b) is set to an off state, the measurement node (e.g., corresponding to interface terminal 502) is electrically coupled to DUT 504a. Also, in FIG. 5B, based on switch 526a is set to an off state and other switch(s) of second switch device 520 (e.g., switch 526b) associated with second common node 522 (e.g., switch 526b) is set to an on state, the bias node (e.g., corresponding to interface terminal 506) is electrically coupled to other DUTs (e.g., DUT 504b) but not DUT 504a. In this non-limiting example, the DC voltage levels at both sides of the transistors forming the switches associated with the common node 512 all correspond to the DC voltage component of test voltage V_test at common node 512. As such, in this non-limiting example, because there are virtually no DC voltage differences across the switches, the leakage current contributable to a subthreshold leakage current of the transistors that constitute the switches at the off state is reduced or eliminated.

FIG. 5C is a schematic diagram of a third switch device 530 in conjunction with other components in a test line as a non-limiting example, in accordance with some embodiments. In some embodiments, third switch device 530 corresponds to switch device 226 in FIGS. 2A-2B or switch device 326 in FIG. 3. In some embodiments, third switch device 530 is a variation based on first switch device 510. As such, components in FIG. 5C that are the same or similar to those in FIG. 5A are given the same reference numbers, and the description thereof is simplified or omitted.

In FIG. 5C, third switch device 530 includes a plurality of branch nodes 514a, 514b, and 514c electrically connectable to corresponding DUTs 504a, 504b, and 504c. In FIG. 5C, third switch device 530 includes a first common node 532, a second common node 534, a first plurality of transistors 542a, 542b, and 542c as switches electrically coupled between first common node 532 and plurality of branch nodes 514a, 514b, and 514c, and a second plurality of transistors 544a, 544b, and 544c as switches electrically coupled between second common node 534 and plurality of branch nodes 514a, 514b, and 514c. In this non-limiting example, the first plurality of transistors 542a, 542b, and 542c corresponds to p-type transistors, and the second plurality of transistors 544a, 544b, and 544c corresponds to n-type transistors.

In FIG. 5C, interface terminal 502 is configured as a measurement node (identified as measurement node 508 in FIG. 5C). In some embodiments, a path selection device 509 (e.g., corresponding to path selection device 222 in FIGS. 2A-2B and path selection device 322 in FIG. 3) is configured to electrically couple measurement node 508 to the first common node 532 or the second common node 534. In some embodiments, the on or off state of each one of the first plurality of transistors 542a, 542b, and 542c and the second plurality of transistors 544a, 544b, and 544c is controllable based on a switch control, such as switch control 228 in FIGS. 2A-2B or switch control 228 in FIG. 2C with a plurality of flip-flop circuits 252, 254, and 256.

In FIG. 5C, based on a first measurement condition (e.g., the DC voltage component at measurement node 508 being greater than a first reference voltage), path selection device 509 is set to electrically couple measurement node 508 to first common node 532, such that the test voltage V_test is applied, and the measurement is performed, through one of the first plurality of transistors 542a, 542b, and 542c (i.e., p-type transistors in this example). In this non-limiting example, based on a second measurement condition (e.g., the DC voltage component at measurement node 508 being less than a second reference voltage), path selection device 509 is set to electrically couple measurement node 508 to second common node 534, such that the test voltage V_test is applied, and the measurement is performed, through one of the second plurality of transistors 544a, 544b, and 544c (i.e., n-type transistors in this example). In this non-limiting example, a voltage difference between the DC voltage level at both sides of the transistors forming the switches that are electrically coupled to measurement node 508 and the substrate bias voltage level of the transistors is reduced by selecting a more suitable type of transistors. As such, in some embodiments, the leakage current attributable to a junction leakage current of the transistors that constitute the switches selected for the measurement session is reduced or eliminated.

Switch devices 520 and 530 are illustrated above separated in FIGS. 5B and 5C. In some embodiments, a switch device is implemented in view of a combination of the configurations described based on switch devices 520 and 530 in FIGS. 5B and 5C. For example, a third plurality of transistors (e.g., p-type transistors) is introduced to supply the bias voltage V_bias when the first plurality of transistors 542a, 542b, and 542a is electrically coupled to measurement node 508, and a fourth plurality of transistors (e.g., n-type transistors) is introduced to supply the bias voltage V_bias when the second plurality of transistors 544a, 544b, and 544a is electrically coupled to measurement node 508.

FIG. 6A is a cross-sectional view of a semiconductor device 600, in accordance with some embodiments. In some embodiments, the cross-sectional view in FIG. 6A is a simplified cross-sectional view, with many features simplified or not depicted.

In FIG. 6A, semiconductor device 600 includes a substrate 610, where one or more transistors are formed on or partially in substrate 610. In FIG. 6A, semiconductor device 600 further includes a plurality of metallization layers (e.g., M0, M1, and M2 layers) and a plurality of via layers (not labeled) over substrate 610. In some embodiments, a number of metallization layers over substrate 610 ranges from 8 to 14. In some embodiments, M0 layer denotes the first metallization layer above substrate 610. In some embodiments, the plurality of metallization layers and the plurality of via layers include a conductive material including copper, aluminum, gold, tungsten, a combination thereof, or the like.

In FIG. 6A, semiconductor device 600, as a non-limiting example, further includes conductive structures disposed under substrate 610. For example, semiconductor device 600 further includes backside metallization layers BM0, BM1, and BM2 and corresponding backside via layers (not labeled). In some embodiments, BM0 layer denotes the first metallization layer under substrate 610. In this example, semiconductor device 600 includes three backside metallization layers and corresponding via layers. In some embodiments, a number of backside metallization layers under substrate 610 ranges from 2 to 6. In some embodiments, a portion or all of the backside conductive structures (e.g., backside metallization layers BM0 and BM1) are at least partially embedded in substrate 610. In some embodiments, backside metallization layers BM0, BM1, and BM2 and the corresponding backside via layers include a conductive material including copper, aluminum, gold, tungsten, a combination thereof, or the like. In some other embodiments, a semiconductor device does not include any backside conductive structures.

In some embodiments, the transistors formed on or partially in the substrate 610 are based on a front-end-of-line (FEOL) stage. In some embodiments, a portion of semiconductor device 600 at and above a given metallization layer (e.g., M2 layer and above) are based on a back-end-of-line (BEOL) stage and/or a middle-end-of-line (MEOL) stage. In some embodiments, each of the FEOL stage, MEOL stage, and BEOL stage corresponds to a set of processes performed at different stages. Different manufacturers may categorize the FEOL stage, MEOL stage, and/or BEOL stage differently, but usually the FEOL stage is performed first, then the MEOL stage if applicable, and then the BEOL stage.

FIG. 6B is a plan view of a DUT 620 based on one metallization layer, in accordance with some embodiments. In this non-limiting example, DUT 620 includes a first conductive structure 622 and a second conductive structure 624. In some embodiments, DUT 620 is used to model adjacent conductive structures within a same metallization layer and corresponding to different nodes. In some embodiments, one or more DUTs based on DUT 620 are formed and included in a test line (e.g., test line example 200 in FIGS. 2A-2B or test line example 300 in FIG. 3). In some embodiments, the one or more DUTs is based on DUT 620 with various metal widths, metal lengths, and/or metal pitches. In some embodiments, one or more stress conditions to be applied to the one or more DUTs based on DUT 620 correspond to applying different voltage differences between the conductive structures corresponding to first conductive structure 622 and second conductive structure 624, and/or under different temperature settings.

In some embodiments, the metal reliability of such metallization layer is derivable based on testing the one or more DUTs based on DUT 620. For example, the leakage or a burnout condition between first conductive structure 622 and second conductive structure 624 is observable based on measuring a resistance, a capacitance, and/or a current between first conductive structure 622 and second conductive structure 624 of DUT 620. In some embodiments, a model for forecasting a long-term performance of components in such metallization layer is derivable based on observing changes of tested DUTs over different voltage and/or temperature settings.

FIG. 6C is a perspective view of a DUT 630 based on two adjacent metallization layers, in accordance with some embodiments. In this non-limiting example, DUT 630 includes a first conductive structure 632 in a first metallization layer and a second conductive structure 634 in a second metallization layer. In some embodiments, DUT 630 is used to model two conductive structures of adjacent metallization layers and belonging to different nodes. In some embodiments, one or more DUTs based on DUT 630 are formed and included in a test line (e.g., test line example 200 in FIGS. 2A-2B or test line example 300 in FIG. 3). In some embodiments, the one or more DUTs are based on DUT 630 with various metal widths, metal lengths, and/or metal pitches. In some embodiments, one or more stress conditions to be applied to the one or more DUTs based on DUT 630 correspond to applying different voltage differences between the conductive structures corresponding to first conductive structure 632 and second conductive structure 634, and/or under different temperature settings.

In some embodiments, the metal reliability of those two metallization layers is derivable based on testing the one or more DUTs based on DUT 630. For example, the leakage or a burnout condition between first conductive structure 632 and second conductive structure 634 is observable based on measuring a resistance, a capacitance, and/or a current between first conductive structure 632 and second conductive structure 634 of DUT 630. In some embodiments, a model for forecasting a long-term performance of components in these metallization layers is derivable based on observing changes of tested DUTs over different voltage and/or temperature settings.

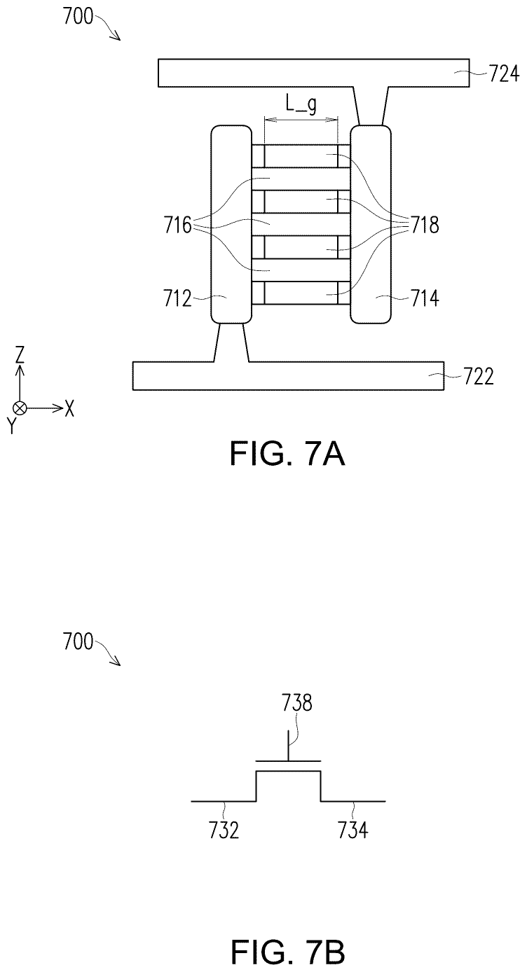

FIG. 7A is a cross-sectional view of a transistor 700 that is usable as the basis for forming and testing DUTs, in accordance with some embodiments. In some embodiments, the cross-sectional view in FIG. 7A is a simplified cross-sectional view, with many features simplified or not depicted.

In FIG. 7A, transistor 700 includes a first epitaxial structure 712, a second epitaxial structure 714, a plurality of nanosheet structures 716 electrically coupled between first epitaxial structure 712 and second epitaxial structure 714, and a plurality of gate structures 718 between first epitaxial structure 712 and second epitaxial structure 714 and adjacent to the plurality of nanosheet structures 716. In FIG. 7A, the plurality of gate structures 718 is electrically separated from first epitaxial structure 712 and second epitaxial structure 714 by spacers (not labeled). In FIG. 7A, each one of the plurality of gate structures 718 has a gate length L_g measurable along a first horizontal direction (e.g., the X direction) and a gate width measurable along a second horizontal direction (e.g., the Y direction, entering the drawing sheet). Also, each one of the plurality of nanosheet structures 716 has a sheet length measurable along the first horizontal direction (e.g., the X direction), a sheet width measurable along the second horizontal direction (e.g., the Y direction), and a sheet height measurable along a vertical direction (e.g., the Z direction). In some embodiments, the plurality of nanosheet structures 716 includes a number of sheets arranged along the vertical direction (e.g., the Z direction).

In FIG. 7A, first epitaxial structure 712 is electrically coupled to a conductive structure 722, and second epitaxial structure 714 is electrically coupled to a conductive structure 724. In some embodiments, first epitaxial structure 712 and second epitaxial structure 714 correspond to the drain/source terminals of transistor 700, and the plurality of gate structures 718 correspond to a gate terminal of transistor 700. In some embodiments, the plurality of nanosheet structures 716 correspond to formation of a conductive channel between the drain/source terminals based on the voltage levels at the gate terminal and the drain/source terminals.

FIG. 7B is a schematic diagram of transistor 700 in FIG. 7A, in accordance with some embodiments. In FIG. 7B, transistor 700 includes a first drain/source terminal 732 that corresponds to first epitaxial structure 712 in FIG. 7A, a second drain/source terminal 734 that corresponds to second epitaxial structure 714, and a gate terminal 738 that corresponds to the plurality of gate structures 718.

In some embodiments, one or more DUTs are formed based on transistor 700 and included in a test line (e.g., test line example 200 in FIGS. 2A-2B or test line example 300 in FIG. 3). In some embodiments, the one or more DUTs are based on transistor 700 with various gate lengths, gate widths, sheet lengths, sheet widths, sheet heights, numbers of sheets of the plurality of nanosheet structures, threshold voltages, or the like, or any combination thereof. In some embodiments, one or more stress conditions to be applied to the one or more DUTs based on transistor 700 correspond to, with or without varying the temperature settings, holding the drain/source terminals 732 and 734 at the same voltage level and applying different voltage levels at the gate terminal 738 for testing gate reliability, holding the second drain/source terminal 734 and the gate terminal 738 at the same voltage level and applying different voltage levels at the first drain/source terminal 732 for testing non-conducting performance, holding the voltages level at the second drain/source terminal 734 and applying different voltage levels at the first drain/source terminal 732 and the gate terminals 738 for testing negative bias temperature instability or positive bias temperature instability.

In some embodiments, one or more parameters of the one or more DUTs are derived based on measuring a resistance, a capacitance, and/or a current between various terminals 732, 734, and 738. In some embodiments, the one or more parameters reflect a burnout condition between the plurality of gate structures 718 and first epitaxial structure 712, the plurality of gate structures 718 and first epitaxial structure 712 and second epitaxial structure 714, and/or the plurality of gate structures 718 and the plurality of nanosheet structures 716. In some embodiments, a model for forecasting a long-term performance of components in such metallization layer is derivable based on observing changes of tested DUTs over different voltage and/or temperature settings.

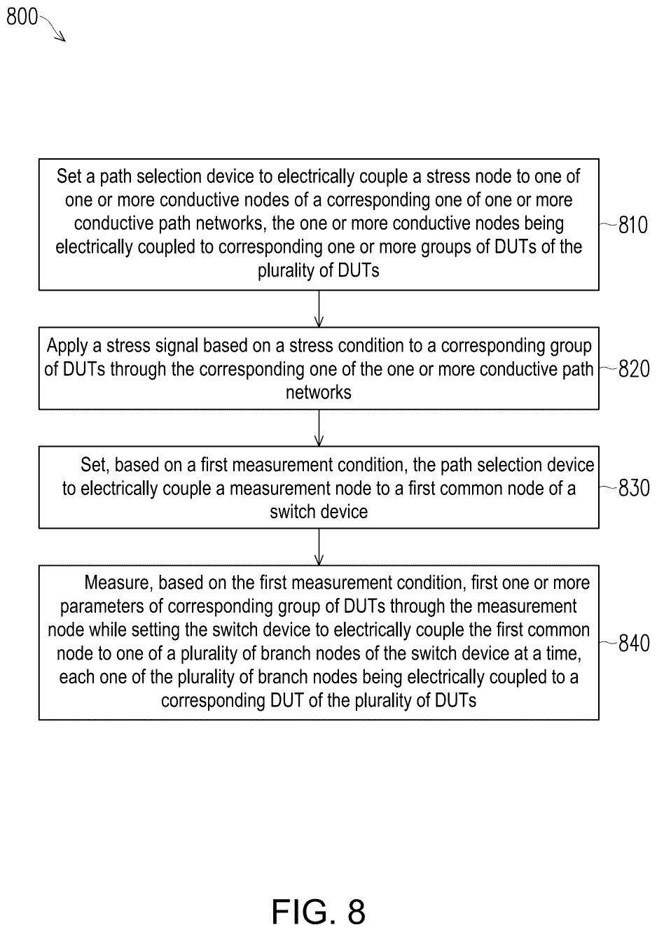

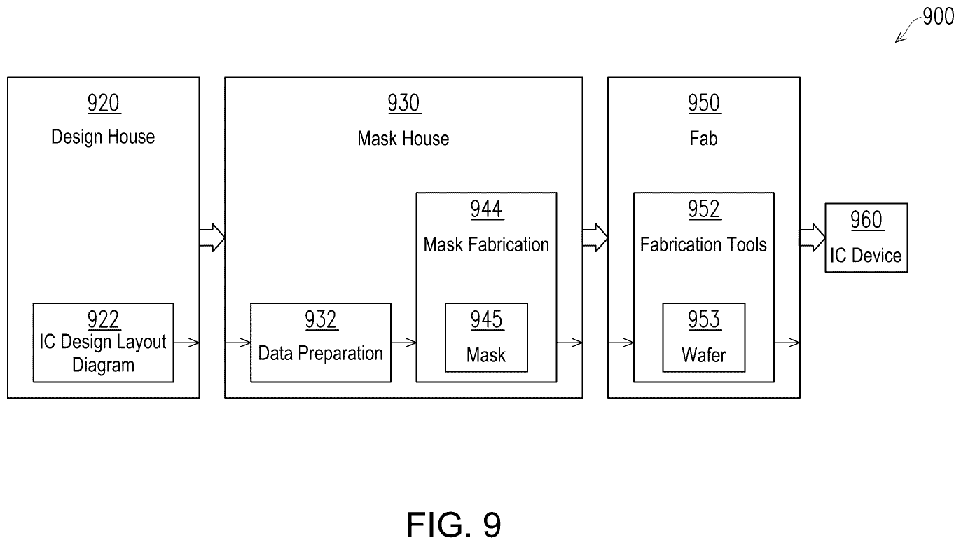

FIG. 8 is a flowchart of a method 800 of testing a plurality of DUTs on a wafer, in accordance with some embodiments. In some embodiments, the semiconductor device based on method 800 corresponds to the examples in FIGS. 3A-8B in view of the configurations in FIGS. 1A-1B. In some embodiments, method 800 is performed in conjunction with an IC manufacturing system as discussed with respect to the IC manufacturing system 900 in FIG. 9. Method 800 includes blocks 810-840.

At block 810, a path selection device (e.g., path selection device 222 in FIG. 2A or path selection device 322 in FIG. 3) is set to electrically couple a stress node (e.g., corresponding to interface terminal 212f in FIG. 2A or interface terminal 312f in FIG. 3) to one of one or more conductive nodes (e.g., corresponding conductive path network 224a in FIG. 2A or conductive path network 324a, 324b, 324c, and 324d in FIG. 3) of a corresponding one of one or more conductive path networks. In some embodiments, the one or more conductive nodes being electrically coupled to corresponding one or more groups of DUTs (e.g., DUTs 232, 234, and 236 in FIG. 2A as one group or groups of DUTs 330a, 330b, 330c, and 330d in FIG. 3) of the plurality of DUTs.

In some embodiments, the setting the path selection device is based on the one or more conductive path networks corresponding to a single conductive path network having a single conductive node electrically coupled to the plurality of DUTs, as described in the example in FIGS. 2A-2B. The flow then proceeds to block 820.

At block 820, a stress signal is applied based on a stress condition to a corresponding group of DUTs through the corresponding one of the one or more conductive path networks. The flow then proceeds to block 830.

At block 830, based on a first measurement condition, the path selection device is set to electrically couple a measurement node (e.g., corresponding to interface terminal 212e in FIG. 2B or interface terminal 312e in FIG. 3) to a first common node (e.g., common node 226a in FIG. 2B or common node 326a in FIG. 3) of a switch device (e.g., switch device 226 in FIG. 2B or switch device 326 in FIG. 3). The flow then proceeds to block 840.

At block 840, based on the first measurement condition, first one or more parameters of corresponding group of DUTs are measured through the measurement node while setting the switch device to electrically couple the first common node to one of a plurality of branch nodes (e.g., branch nodes 226b, 226c, and 226d in FIG. 2B or branch nodes 328a, 328b, 328c, and 328d in FIG. 3) of the switch device at a time. In some embodiments, each one of the plurality of branch nodes is electrically coupled to a corresponding DUT of the plurality of DUTs.

In some embodiments, the switch device includes a plurality of transistors electrically coupled between the first common node and the plurality of branch nodes, as described in the examples in FIGS. 2C and 5A-5C. In some embodiments, method 800 further includes controlling an on or off state of each one of the plurality of transistors based on a corresponding one of a plurality of flip-flop circuits.

In some embodiments, method 800 further includes applying a direct current bias voltage to a second common node (e.g., common node 522 in FIG. 5B) of the switch device. In some embodiments, the direct current bias voltage corresponds to a direct current voltage component at the measurement node (e.g., test voltage V_test at the measurement node corresponding to interface terminal 502 in FIG. 5B). In some embodiments, the measuring the first one or more parameters of the corresponding group of DUTs through the measurement node is performed further based on setting the switch device to electrically decouple the second common node from one of the plurality of branch nodes of the switch device at a time, and each DUT of the plurality of DUTs being either electrically coupled to the first common node or to the second common node at a time, as described in the example in FIG. 5B. in some embodiments, the switch device includes a first plurality of transistors electrically coupled between the first common node and the plurality of branch nodes, and a second plurality of transistors electrically coupled between the second common node and the plurality of branch nodes. In some embodiments, method 800 further includes controlling an on or off state of each one of the first plurality of transistors and an on or off state of each one of the second plurality of transistors based on a corresponding one of a plurality of flip-flop circuits.

In some embodiments, method 800 further includes setting, based on a second measurement condition, the path selection device to electrically couple the measurement node to a third common node of the switch device. In some embodiments, method 800 further includes measuring, based on the second measurement condition, second one or more parameters of corresponding group of DUTs through the measurement node while setting the switch device to electrically couple the third common node to one of the plurality of branch nodes of the switch device at a time, as described in the example in FIG. 5B. in some embodiments, the first switch device includes a plurality of p-type transistors electrically coupled between the first common node and the plurality of branch nodes, and a plurality of n-type transistors electrically coupled between the third common node and the plurality of branch nodes. In some embodiments, method 800 further includes controlling an on or off state of each one of the plurality of p-type transistors and an on or off state of each one of the plurality of n-type transistors based on a corresponding one of a plurality of flip-flop circuits.

In some embodiments, the one or more embodiments described in this disclosure are applicable to test or monitor one or more parameters regarding semiconductor components (e.g., transistors and/or diodes), FEOL components, BEOL components, conductive structures in one or more front side metallization layers (e.g., interconnection structures and/or front-side power distribution networks), conductive structures in one or more back side metallization layers (e.g., interconnection structures, back-side power distribution networks, and/or super power rail structures), though-substrate-via (TSV) structures for a 3DIC application, or the like, or any combination thereof. In some embodiments, the testing or monitoring according to one or more embodiments of this disclosure increased the overall testing speed and usable for establishing an aging model efficiently.

FIG. 9 is a block diagram of an IC manufacturing system 900, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using manufacturing system 900.

In FIG. 9, IC manufacturing system 900 includes entities, such as a design house 920, a mask house 930, and an IC manufacturer/fabricator (fab) 950, that interact with one another in the design, development, and manufacturing cycles and/or services related to manufacturing an IC device 960. The entities in system 900 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 920, mask house 930, and IC fab 950 is owned by a single larger company. In some embodiments, two or more of design house 920, mask house 930, and IC fab 950 coexist in a common facility and use common resources.

Design house (or design team) 920 generates an IC design layout diagram 922 (e.g., a layout plan). IC design layout diagram 922 includes various geometrical patterns designed for an IC device 960. The geometrical patterns correspond to patterns of metal, oxide, or semiconductor layers that make up the various components of IC device 960 to be fabricated. The various layers combine to form various IC features. For example, a portion of IC design layout diagram 922 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 920 implements a proper design procedure to form IC design layout diagram 922. The design procedure includes one or more of logic design, physical design or place and route. IC design layout diagram 922 is presented in one or more data files having information of the geometrical patterns. For example, IC design layout diagram 922 can be expressed in a GDSII file format or DFII file format.

Mask house 930 includes data preparation 932 and mask fabrication 944. Mask house 930 uses IC design layout diagram 922 to manufacture one or more masks 945 to be used for fabricating the various layers of IC device 960 according to IC design layout diagram 922. Mask house 930 performs mask data preparation 932, where IC design layout diagram 922 is translated into a representative data file (RDF). Mask data preparation 932 provides the RDF to mask fabrication 944. Mask fabrication 944 includes a mask writer. A mask writer converts the RDF to an image on a substrate, such as a mask (reticle) 945 or a semiconductor wafer 953. The design layout diagram 922 is manipulated by mask data preparation 932 to comply with particular characteristics of the mask writer and/or requirements of IC fab 950. In FIG. 9, mask data preparation 932 and mask fabrication 944 are illustrated as separate elements. In some embodiments, mask data preparation 932 and mask fabrication 944 can be collectively referred to as mask data preparation.

In some embodiments, mask data preparation 932 includes optical proximity correction (OPC) which uses lithography enhancement techniques to compensate for image errors, such as those that can arise from diffraction, interference, other process effects and the like. OPC adjusts IC design layout diagram 922. In some embodiments, mask data preparation 932 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 932 includes a mask rule checker (MRC) that checks the IC design layout diagram 922 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 922 to compensate for photolithographic implementation effects during mask fabrication 944, which may undo part of the modifications performed by OPC in order to meet mask creation rules.

In some embodiments, mask data preparation 932 includes lithography process checking (LPC) that simulates processing that will be implemented by IC fab 950 to fabricate IC device 960. LPC simulates this processing based on IC design layout diagram 922 to create a simulated manufactured device, such as IC device 960. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 922.

It should be understood that the above description of mask data preparation 932 has been simplified for the purposes of clarity. In some embodiments, data preparation 932 includes additional features such as a logic operation (LOP) to modify the IC design layout diagram 922 according to manufacturing rules. Additionally, the processes applied to IC design layout diagram 922 during data preparation 932 may be executed in a variety of different orders.

After mask data preparation 932 and during mask fabrication 944, a mask 945 or a group of masks 945 are fabricated based on the modified IC design layout diagram 922. In some embodiments, mask fabrication 944 includes performing one or more lithographic exposures based on IC design layout diagram 922. In some embodiments, an electron-beam (e-beam) or a mechanism of multiple e-beams is used to form a pattern on a mask (photomask or reticle) 945 based on the modified IC design layout diagram 922. Mask 945 can be formed in various technologies. In some embodiments, mask 945 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 945 includes a transparent substrate (e.g., fused quartz) and an opaque material (e.g., chromium) coated in the opaque regions of the binary mask. In another example, mask 945 is formed using a phase shift technology. In a phase shift mask (PSM) version of mask 945, various features in the pattern formed on the phase shift mask are configured to have proper phase difference to enhance the resolution and imaging quality. In various examples, the phase shift mask can be attenuated PSM or alternating PSM. The mask(s) generated by mask fabrication 944 is used in a variety of processes. For example, such a mask(s) is used in an ion implantation process to form various doped regions in semiconductor wafer 953, in an etching process to form various etching regions in semiconductor wafer 953, and/or in other suitable processes.

IC fab 950 is an IC fabrication business that includes one or more manufacturing facilities for the fabrication of a variety of different IC products. In some embodiments, IC fab 950 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 950 includes fabrication tools 952 configured to execute various manufacturing operations on semiconductor wafer 953 such that IC device 960 is fabricated in accordance with the mask(s), e.g., mask 945. In various embodiments, fabrication tools 952 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 950 uses mask(s) 945 fabricated by mask house 930 to fabricate IC device 960. Thus, IC fab 950 at least indirectly uses IC design layout diagram 922 to fabricate IC device 960. In some embodiments, semiconductor wafer 953 is fabricated by IC fab 950 using mask(s) 945 to form IC device 960. In some embodiments, the IC fabrication includes performing one or more lithographic exposures based at least indirectly on IC design layout diagram 922. Semiconductor wafer 953 includes a silicon substrate or other proper substrate having material layers formed thereon. Semiconductor wafer 953 further includes one or more of various doped regions, dielectric features, multilevel interconnects, and the like (formed at subsequent manufacturing steps).

In some aspects, a testing apparatus for testing a plurality of devices-under-test (DUTs) includes one or more interface terminals, including a first interface terminal configured as a measurement node and a second interface terminal configured as a stress node, or including the first interface terminal configured as the measurement node and the stress node. The testing apparatus includes a switch device including a first common node and a plurality of branch nodes, each one of the plurality of branch nodes being electrically connectable to a corresponding DUT of the plurality of DUTs, and the switch device being configured to electrically couple the first common node to one of the plurality of branch nodes at a time. The testing apparatus further includes one or more conductive path networks corresponding to one or more conductive nodes that are electrically connectable to corresponding one or more groups of DUTs of the plurality of DUTs, and a path selection device configured to electrically couple the measurement node to the first common node, or to electrically couple the stress node to one of the one or more conductive nodes.

In some aspects, a method of testing a plurality of devices-under-test (DUTs) on a wafer includes setting a path selection device to electrically couple a stress node to one of one or more conductive nodes of a corresponding one of one or more conductive path networks, the one or more conductive nodes being electrically coupled to corresponding one or more groups of DUTs of the plurality of DUTs. The method includes applying a stress signal based on a stress condition to a corresponding group of DUTs through the corresponding one of the one or more conductive path networks, and setting, based on a first measurement condition, the path selection device to electrically couple a measurement node to a first common node of a switch device. The method further includes measuring, based on the first measurement condition, first one or more parameters of corresponding group of DUTs through the measurement node while setting the switch device to electrically couple the first common node to one of a plurality of branch nodes of the switch device at a time, each one of the plurality of branch nodes being electrically coupled to a corresponding DUT of the plurality of DUTs.

In some aspects, a wafer includes one or more die areas corresponding to formation of one or more dies, a scribe line adjacent to the one or more die areas, and a plurality of devices-under-test (DUTs) in the scribe line or the one or more die areas. The wafer includes a plurality of conductive pads in the scribe line, the plurality of conductive pads including a first conductive pad corresponding to a measurement node and a second conductive pad corresponding to a stress node, or including the first conductive pad corresponding to the measurement node and the stress node. The wafer includes a switch device in the scribe line or the one or more die areas, the switch device including a first common node and a plurality of branch nodes, each one of the plurality of branch nodes being electrically connectable to a corresponding DUT of the plurality of DUTs, and the switch device being configured to electrically couple the first common node to one of the plurality of branch nodes at a time. The wafer includes one or more conductive path networks in the scribe line or the one or more die areas, the one or more conductive path networks corresponding to one or more conductive nodes that are electrically connectable to corresponding one or more groups of DUTs of the plurality of DUTs. The wafer further includes a path selection device in the scribe line or the one or more die areas, the path selection device being configured to electrically couple the measurement node to the first common node, or to electrically couple the stress node to one of the one or more conductive nodes.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure and that they may make various changes, substitutions, and alterations herein without departing from the spirit and scope of the present disclosure.

What is claimed is:

1. A testing apparatus for testing a plurality of devices-under-test (DUTs), comprising:
one or more interface terminals, including a first interface terminal configured as a measurement node and a second interface terminal configured as a stress node, or including the first interface terminal configured as the measurement node and the stress node;
a switch device including a first common node and a plurality of branch nodes, each one of the plurality of branch nodes being electrically connectable to a corresponding DUT of the plurality of DUTs, and the switch device being configured to electrically couple the first common node to one of the plurality of branch nodes at a time;
one or more conductive path networks corresponding to one or more conductive nodes that are electrically connectable to corresponding one or more groups of DUTs of the plurality of DUTs; and
a path selection device configured to electrically couple the measurement node to the first common node, or to electrically couple the stress node to one of the one or more conductive nodes.

2. The testing apparatus of claim 1, wherein
the switch device includes a plurality of transistors electrically coupled between the first common node and the plurality of branch nodes, and
the testing apparatus further comprises a plurality of flip-flop circuits, each one of the plurality of flip-flop circuits being configured to control an on or off state of a corresponding one of the plurality of transistors.

3. The testing apparatus of claim 1, wherein
the one or more conductive path networks correspond to a single conductive path network having a single conductive node electrically connectable to the plurality of DUTs.

4. The testing apparatus of claim 1, wherein
the switch device further includes a second common node,
the switch device is further configured to electrically decouple the second common node from one of the plurality of branch nodes at a time,
each DUT of the plurality of DUTs is either electrically coupled to the first common node or to the second common node at a time, and
the one or more interface terminals further include a third interface terminal configured as a bias node electrically coupled to the second common node.

5. The testing apparatus of claim 4, wherein
the switch device includes
a first plurality of transistors electrically coupled between the first common node and the plurality of branch nodes, and
a second plurality of transistors electrically coupled between the second common node and the plurality of branch nodes, and
the testing apparatus further comprises a plurality of flip-flop circuits, each one of the plurality of flip-flop circuits being configured to control an on or off state of a corresponding one of the first plurality of transistors and an on or off state of a corresponding one of the second plurality of transistors.

6. The testing apparatus of claim 1, wherein
the switch device further includes a third common nodes,
the switch device is further configured to electrically couple the third common node to one of the plurality of branch nodes at a time, and
the path selection device is configured to electrically couple the measurement node to the first common node or the third common node.

7. The testing apparatus of claim 6, wherein
the switch device includes
a plurality of p-type transistors electrically coupled between the first common node and the plurality of branch nodes, and
a plurality of n-type transistors electrically coupled between the third common node and the plurality of branch nodes, and
the testing apparatus further comprises a plurality of flip-flop circuits, each one of the plurality of flip-flop circuits configured to control an on or off state of a corresponding one of the plurality of p-type transistors and an on or off state of a corresponding one of the plurality of n-type transistors.

8. A method of testing a plurality of devices-under-test (DUTs) on a wafer, comprising:
setting a path selection device to electrically couple a stress node to one of one or more conductive nodes of a corresponding one of one or more conductive path networks, the one or more conductive nodes being electrically coupled to corresponding one or more groups of DUTs of the plurality of DUTs;
applying a stress signal based on a stress condition to a corresponding group of DUTs through the corresponding one of the one or more conductive path networks;
setting, based on a first measurement condition, the path selection device to electrically couple a measurement node to a first common node of a switch device; and
measuring, based on the first measurement condition, first one or more parameters of a corresponding group of DUTs through the measurement node while setting the switch device to electrically couple the first common node to one of a plurality of branch nodes of the switch device at a time, each one of the plurality of branch nodes being electrically coupled to a corresponding DUT of the plurality of DUTs.

9. The method of claim 8, wherein
the switch device includes a plurality of transistors electrically coupled between the first common node and the plurality of branch nodes, and
the method further includes controlling an on or off state of each one of the plurality of transistors based on a corresponding one of a plurality of flip-flop circuits.

10. The method of claim 8, wherein
the setting the path selection device is based on the one or more conductive path networks corresponding to a single conductive path network having a single conductive node electrically coupled to the plurality of DUTs.

11. The method of claim 8, further comprising:
applying a direct current bias voltage to a second common node of the switch device, the direct current bias voltage corresponding to a direct current voltage component at the measurement node,
wherein the measuring the first one or more parameters of the corresponding group of DUTs through the measurement node is performed further based on setting the switch device to electrically decouple the second common node from one of the plurality of branch nodes of the switch device at a time, and each DUT of the plurality of DUTs being either electrically coupled to the first common node or to the second common node at a time.

12. The method of claim 11, wherein
the switch device includes
a first plurality of transistors electrically coupled between the first common node and the plurality of branch nodes, and
a second plurality of transistors electrically coupled between the second common node and the plurality of branch nodes, and
the method further includes controlling an on or off state of each one of the first plurality of transistors and an on or off state of each one of the second plurality of transistors based on a corresponding one of a plurality of flip-flop circuits.

13. The method of claim 8, further comprising:
setting, based on a second measurement condition, the path selection device to electrically couple the measurement node to a third common node of the switch device; and
measuring, based on the second measurement condition, second one or more parameters of a corresponding group of DUTs through the measurement node while setting the switch device to electrically couple the third common node to one of the plurality of branch nodes of the switch device at a time.

14. The method of claim 13, wherein:
the switch device includes
a plurality of p-type transistors electrically coupled between the first common node and the plurality of branch nodes, and
a plurality of n-type transistors electrically coupled between the third common node and the plurality of branch nodes, and
the method further includes controlling an on or off state of each one of the plurality of p-type transistors and an on or off state of each one of the plurality of n-type transistors based on a corresponding one of a plurality of flip-flop circuits.

15. A wafer, comprising:
one or more die areas corresponding to formation of one or more dies;
a scribe line adjacent to the one or more die areas;
a plurality of devices-under-test (DUTs) in the scribe line or the one or more die areas;
a plurality of conductive pads in the scribe line, the plurality of conductive pads including a first conductive pad corresponding to a measurement node and a second conductive pad corresponding to a stress node, or including the first conductive pad corresponding to the measurement node and the stress node;
a switch device in the scribe line or the one or more die areas, the switch device including a first common node and a plurality of branch nodes, each one of the plurality of branch nodes being electrically connectable to a corresponding DUT of the plurality of DUTs, and the switch device being configured to electrically couple the first common node to one of the plurality of branch nodes at a time;
one or more conductive path networks in the scribe line or the one or more die areas, the one or more conductive path networks corresponding to one or more conductive nodes that are electrically connectable to corresponding one or more groups of DUTs of the plurality of DUTs; and
a path selection device in the scribe line or the one or more die areas, the path selection device being configured to electrically couple the measurement node to the first common node, or to electrically couple the stress node to one of the one or more conductive nodes.

16. The wafer of claim 15, wherein
the switch device includes a plurality of transistors electrically coupled between the first common node and the plurality of branch nodes, and
the wafer further comprises a plurality of flip-flop circuits in the scribe line or the one or more die areas, each one of the plurality of flip-flop circuits being configured to control an on or off state of a corresponding one of the plurality of transistors.

17. The wafer of claim 15, wherein
the switch device further includes a second common node,
the switch device is further configured to electrically decouple the second common node from one of the plurality of branch nodes at a time,
each DUT of the plurality of DUTs is either electrically coupled to the first common node or to the second common node at a time, and
the plurality of conductive pads further include a third conductive pad corresponding to a bias node electrically coupled to the second common node.

18. The wafer of claim 17, wherein
the switch device includes
a first plurality of transistors electrically coupled between the first common node and the plurality of branch nodes, and
a second plurality of transistors electrically coupled between the second common node and the plurality of branch nodes, and
the wafer further comprises a plurality of flip-flop circuits in the scribe line or the one or more die areas, each one of the plurality of flip-flop circuits being configured to control an on or off state of a corresponding one of the first plurality of transistors and an on or off state of a corresponding one of the second plurality of transistors.

19. The wafer of claim 15, further comprising:
the switch device further includes a third common node,
the switch device is further configured to electrically couple the first common node to one of the plurality of branch nodes at a time, and
the path selection device is configured to electrically couple the measurement node to the first common node or the third common node.

20. The wafer of claim 19, wherein
the switch device includes
a plurality of p-type transistors electrically coupled between the first common node and the plurality of branch nodes, and
a plurality of n-type transistors electrically coupled between the third common node and the plurality of branch nodes, and
the wafer further comprises a plurality of flip-flop circuits in the scribe line or the one or more die areas, each one of the plurality of flip-flop circuits being configured to control an on or off state of a corresponding one of the plurality of p-type transistors and an on or off state of a corresponding one of the plurality of n-type transistors.
